(19) United States
(12) Patent Application Publication
(10) Pub. No.: US 2025/0085257 A1
(43) Pub. Date: Mar. 13, 2025

(54) Wear Sensor

(71) Applicant: K F GROUP PTY LTD, East Perth, Western Australia (AU)

(72) Inventor: Con Kamaras, East Perth (AU)

(21) Appl. No.: 18/720,473

(22) PCT Filed: Dec. 14, 2022
(86) PCT No.: PCT/AU2022/051508

§ 371 Date: Jun. 14, 2024

(30) Foreign Application Priority Data
Dec. 15, 2021 (AU) 2021904075

(51) Int. Cl. G01N 29/04; G01N 29/24

(52) U.S. Cl. CPC G01N 29/04; G01N 29/2437; G01N 2291/023; G01N 2291/02854; G01N 2291/106

(57) ABSTRACT

A wear sensor (10) comprising a body (12) including at least first and second ultrasonic transducers (14) for sending and/or receiving ultrasonic signals and a connection member (18). The connection member (18) comprises a planar first end portion (30) having connectors thereon for receiving signals from and sending signals to the ultrasonic transducers (14) and a planar second end portion (32) having a plurality of tabs (34) extending outwardly from a first side (36) edge thereof connected by conductors on the connection member (18) to the connectors. The second end portion (32) is embedded within the body (12) of the wear sensor (10) adjacent the transducers (14) and the tabs (34) are bent out of the plane of the second end portion (32) of the connection member (18) for connection to the transducers (14).

### FIELD OF THE INVENTION

The present invention relates to a sensor for detecting wear in industrial parts and a system incorporating a plurality of such sensors.

### BACKGROUND TO THE INVENTION

Monitoring wear in industrial components is significant both in terms of preventing failures in the equipment and scheduling appropriate maintenance in a way that reduces downtime costs. One particular example comprises monitoring the wearing of wear plates used to line transfer chutes in conveyor systems. The transfer chutes are lined with plates which will wear over time and eventually need to be replaced. Given the significant expense of shutdowns of such large systems, it is particularly important to ensure that the wearing parts are replaced before the wear becomes too great, but not any more often than is necessary.

Present systems utilise ultrasonic sensors positioned on the wearing components to detect wear. The sensors send an ultrasonic signal and detect a return signal in order to determine changes in thickness of the parts associated with wear. Such sensors are relatively expensive however and there are therefore limits on the number that can be applied in a cost effective manner. Using a larger number of sensors however can provide greater data regarding wear patterns which can enhance analysis in a way which can lead to significant operational cost savings.

The present invention relates to a wear sensor designed such that it is effective in operation and relatively simple to construct and therefore more cost effective to produce in larger quantities.

### SUMMARY OF THE INVENTION

According to one aspect of the present invention there is provided a wear sensor comprising:

a body including at least first and second ultrasonic transducers for sending and receiving ultrasonic signals; and

a connection member comprising a planar first end portion having connectors thereon for receiving signals from and sending signals to the ultrasonic transducers, and a planar second end portion having a plurality of tabs extending outwardly from a first side edge thereof connected by conductors on the connection member to the connectors;

wherein the second end portion is embedded within the body of the wear sensor adjacent the first and second ultrasonic transducers and wherein the tabs are bent out of the plane of the second end portion of the connection member for connection to the transducers.

Preferably the first and second transducers comprise planar piezo elements and the second end portion of the connection member is oriented within the body perpendicular to the piezo elements with a first side edge thereof adjacent the piezo elements.

Preferably the body is cylindrical and the first and second piezo elements are co-planar and semi-circular and wherein the second end portion of the connection member is oriented such that the first side edge is adjacent central edges of the piezo elements.

Preferably four tabs are provided such that each of the piezo elements may have one of the tabs folded adjacent a first surface thereof and one of the tabs folded to be adjacent a second surface thereof.

Preferably the first side edge includes recessed portions such that one of the tabs for connection to each of the piezo elements extends from the recessed portion.

Preferably the connection member comprises a flexible board and the second end portion is folded to be perpendicular to the first end portion.

In a preferred embodiment, the first end portion includes a further bend to define an intermediate section of the first end portion located adjacent the body such that intermediate section is parallel to the longitudinal axis of the body and perpendicular to the second end portion and such that the first end portion of the connection member extends away from the body being perpendicular to the central longitudinal axis of the body.

Preferably the body includes a backing layer adjacent a second end of the body and a matching layer adjacent the first end.

Preferably the matching layer has a depth greater than the backing layer such that the transducers are located closer to the second end of the body than the first end.

In a preferred embodiment, surfaces of the matching layer adjacent the transducers are angled such that the first and second piezo elements are angled relative to each other.

Preferably a case is provided to receive the body.

Preferably the body includes also a cap extending across the case at the second end thereof above the backing layer.

In a further embodiment, the body is rectangular.

In one embodiment, there are provided third, fourth and fifth piezo elements with each of the piezo element being rectangular.

Preferably the second, third, fourth and fifth piezo elements are each located adjacent a side of the first piezo element.

Preferably the second end portion of the connection member includes bends such that the first edge thereof extends between adjacent pairs of piezo elements.

### BRIEF DESCRIPTION OF THE DRAWINGS

The invention will now be described, by way of example, with reference to the following drawings, in which:

FIG. 1 is an upper perspective view of a wear sensor in accordance with the present invention;

FIG. 2 is a side view of the wear sensor of FIG. 1 with the case and cap removed to show internal features;

FIG. 3a is an upper perspective view of the wear sensor of FIG. 1;

FIG. 3b is a top view of the wear sensor of FIG. 1;

FIG. 3c is a lower perspective view of the wear sensor of FIG. 1;

FIG. 3d is a bottom view of the wear sensor of FIG. 1;

FIG. 3e is an end view of the wear sensor of FIG. 1;

FIG. 3f is a side view of the wear sensor of FIG. 1;

FIG. 4a is an upper perspective view of the wear sensor of FIG. 1 with the cap, case and backing layer removed;

FIG. 4b is a top view of the wear sensor of FIG. 4a;

FIG. 4c is a lower perspective view of the wear sensor of FIG. 4a;

FIG. 4d is a bottom view of the wear sensor of FIG. 4a;

FIG. 4e is an end view of the wear sensor of FIG. 4a;

FIG. 4f is a side view of the wear sensor of FIG. 4a;

FIG. 5a is an upper perspective view of a wear sensor of FIG. 1 showing only the piezo elements and the connection member;

FIG. 5b is a top view of the wear sensor of FIG. 5a;

FIG. 5c is a lower perspective view of the wear sensor of FIG. 5a;

FIG. 5d is a bottom view of the wear sensor of FIG. 5a;

FIG. 5e is an end view of the wear sensor of FIG. 5a;

FIG. 5f is a side view of the wear sensor of FIG. 5a;

FIG. 6a is an upper perspective view of a wear sensor of FIG. 1 showing only the connection member;

FIG. 6b is a top view of the wear sensor of FIG. 6a;

FIG. 6c is a lower perspective view of the wear sensor of FIG. 6a;

FIG. 6d is a bottom view of the wear sensor of FIG. 6a;

FIG. 6e is an end view of the wear sensor of FIG. 6a;

FIG. 6f is a side view of the wear sensor of FIG. 6a;

FIG. 7 is a first side view of the connection member of the wear sensor in an unfolded state;

FIG. 8 is a second side view of the connection member of the wear sensor in the unfolded state;

FIG. 9 is a view of a rear surface of a wear plate to which a plurality of wear sensors are connected;

FIG. 10 is a view of the wear plate showing a housing secured to one of the securing bolts;

FIG. 11a is an upper perspective view of a second embodiment of a wear sensor in accordance with the present invention with the cap and backing layer removed;

FIG. 11b is a top view of the wear sensor of FIG. 11a;

FIG. 12 is an upper perspective view of the connection member of FIG. 11 is a folded state;

FIG. 13a is an upper perspective view of the connection member of FIG. 11 in an unfolded state; and

FIG. 13b is a top view of the connection member of FIG. 13a.

### DETAILED DESCRIPTION OF PREFERRED EMBODIMENTS

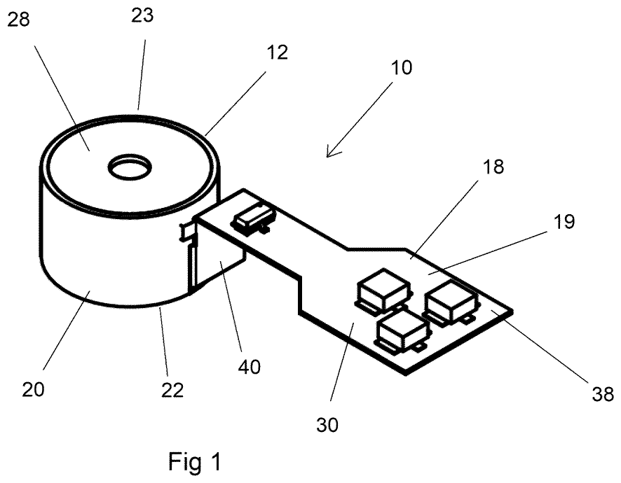

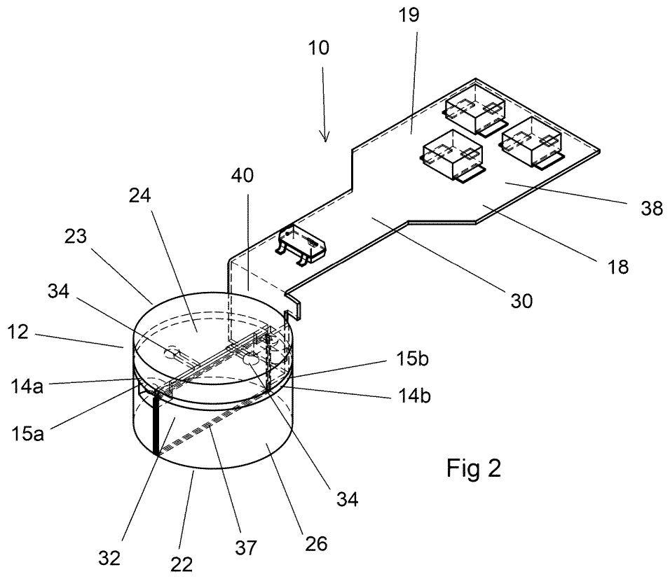

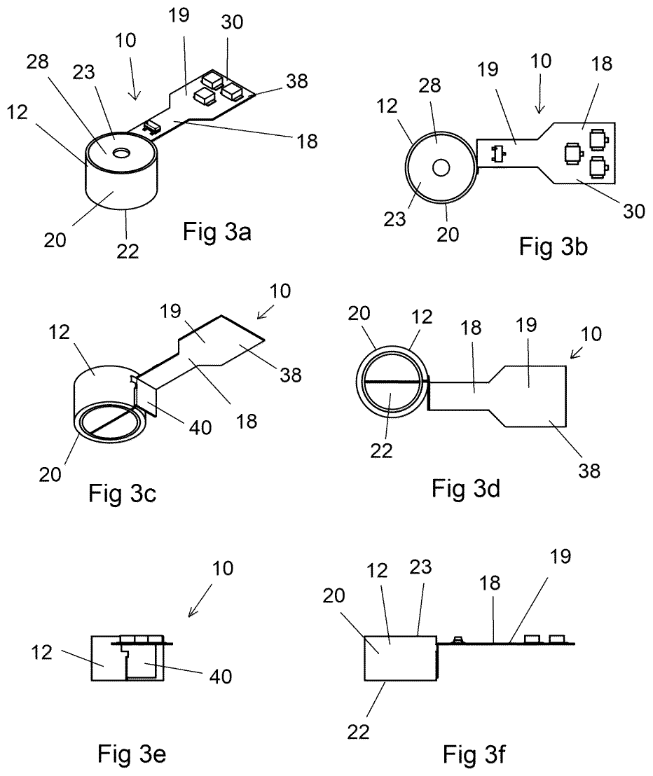

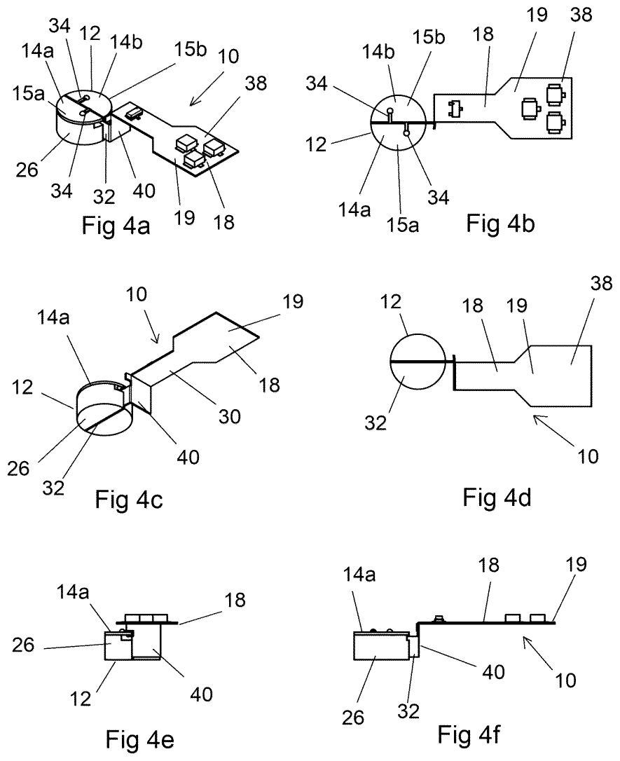

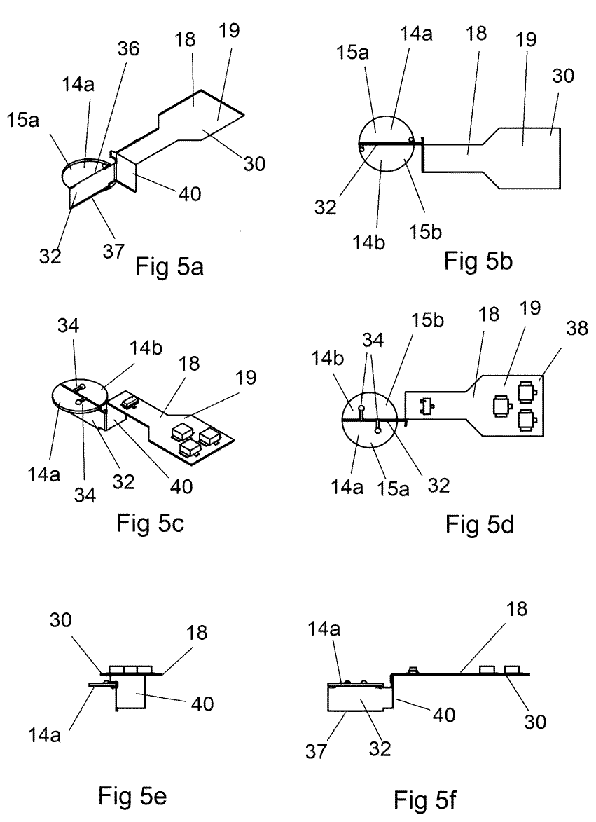

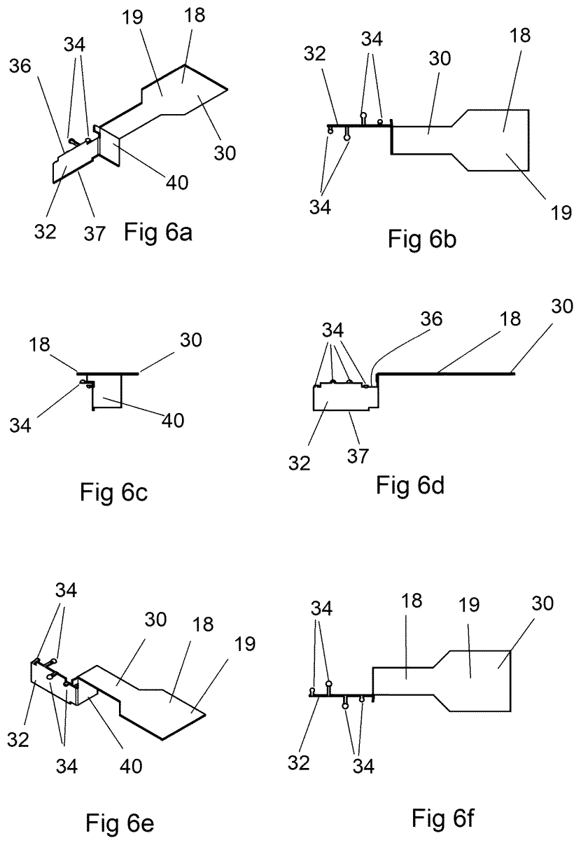

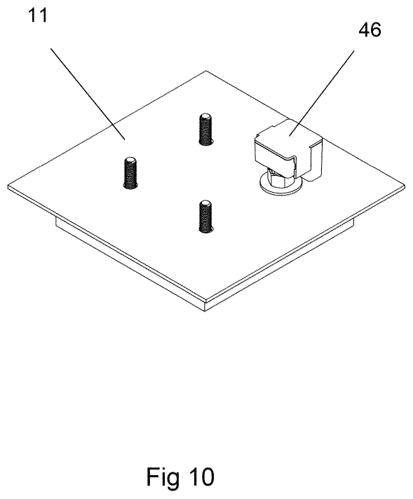

Referring to the Figures, there is shown a wear sensor 10 comprising generally a body 12, having a plurality of ultrasonic transducers 14 and a connection member 18. In the embodiment of FIGS. 1 to 10, there are provided first and second ultrasonic transducers 14a and 14b, however an alternative number of transducers may be used.

The body 12 in the embodiment shown is generally cylindrical such that the body 12 includes first and second ends 22 and 23 and is enclosed in a cylindrical case 20. The first and second ultrasonic transducers 14a and 14b form a generally circular layer located between the first and second ends 22 and 23. The first and second ultrasonic transducers 14a and 14b in the embodiment shown comprise first and second piezo elements 15a and 15b. The piezo elements 15a and 15b each comprise a flat plate being generally semicircular in shape such that when the piezo elements 15a and 15b are arranged adjacent each other within the body 12, the piezo elements 15 extend transversely across the extents of the body 12.

The body 12 comprises a plurality of layers provided around the transducers 14a and 14b. In the embodiment shown, the layers include a backing layer 24 adjacent the second end 23 and a matching layer 26 adjacent the first end 22. The materials of the backing layer 24 and the matching layer 26 may be selected in order to optimise operation of the wear sensor 10. In the embodiment shown, the matching layer 26 has a depth greater than the backing layer 24 such that the transducers 14a and 14b are located closer to the second end 23 of the body 12. The surfaces of the matching layer 26 adjacent the transducers 14a and 14b may also be angled such that the first and second piezo elements 15a and 15b are angled slightly relative to each other. The body 12 includes also a cap 28 extending across the case 20 at the second end 23 thereof, above the backing layer 24.

The connection member 18 comprises a flexible board 19 which provides electrical connections between the transducers 14a and 14b and a wear monitoring system of which the wear sensor 10 forms a part. The connection member 18 includes a planar first end portion 30 and a planar second end portion 32. The first end portion 30 includes a plurality of connectors for connection to the wear monitoring system. The second end portion 32 includes a plurality of tabs 34 extending outwardly from a side of the second end portion 32. The connection member 18 is provided also with a plurality of conductors extending from the first end portion 30 to the tabs 34 on the second end portion 32. The conductors provide electrical connection between the connectors and the tabs 34.

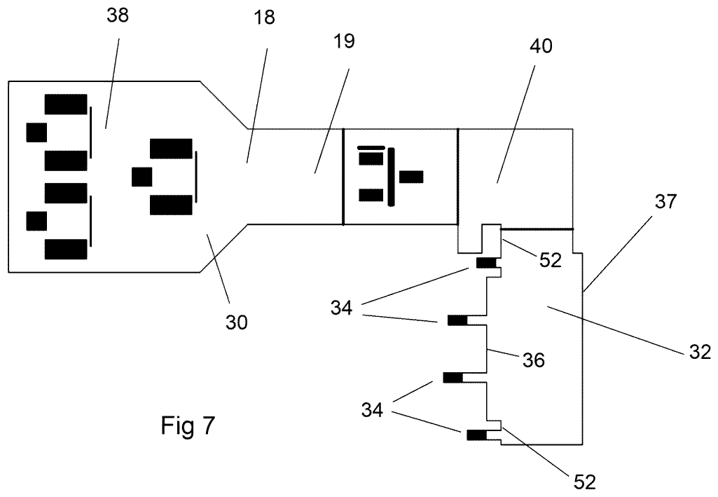

The planar second end portion 32 is embedded within the body 12 between the transducers 14a and 14b and the first end 22 of the body 12. In the embodiment of FIGS. 1 to 13, the planar second end portion 32 is oriented such that it is parallel to a central longitudinal axis of the body 12. That is, the second end portion 32 is oriented generally perpendicular to the first and second piezo elements 15a and 15b. A first side edge 36 of the second end portion 32 is located adjacent central edges of the piezo elements 15a and 15b. A second side edge 37 of the second end portion 32 is located adjacent the first end 22 of the body 12. The tabs 34 extend outwardly from the first side edge 36 of the second end portion 32 of the connection member 18. The first side edge 36 includes recessed portions 52 from which extends one of the tabs 34 for each of the piezo elements 15 (as best seen in FIG. 7) to allow each pair of tabs 34 to more easily connect to opposite surfaces of the piezo element 15.

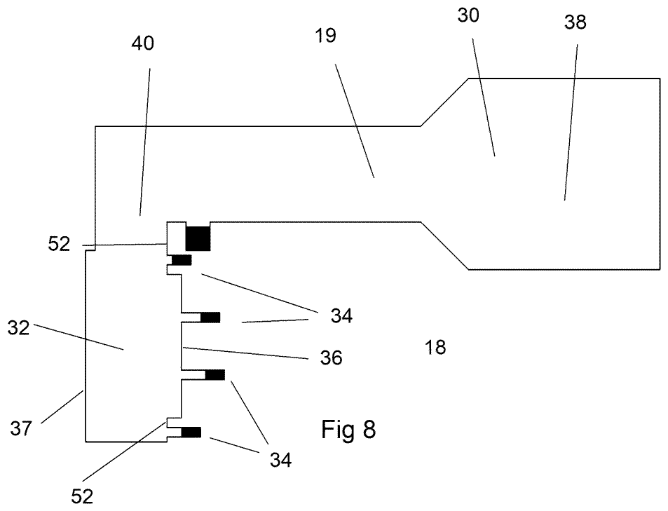

The flexible board 19 is formed from a material such that it may be constructed in a flat configuration (as seen in FIGS. 7 and 8) and bent into the required folded configuration. The tabs 34 may be bent to be perpendicular to the second end portion 32 such that the tabs 34 extend adjacent faces of the first and second piezo elements 15a and 15b. In the embodiment shown, there are provided four such tabs 34 such that each of the piezo elements 15a and 15b may have one of the tabs 34 adjacent a first surface thereof and one of the tabs 34 adjacent a second surface thereof. The tabs 34 may be connected to the surfaces of the piezo elements 15a and 15b by soldering.

As can be seen in FIGS. 7 and 8, the connection member 18 is generally L-shaped when in the flat configuration such that the first end portion 30 is elongate and the second end portion 32 is elongate and extends perpendicular to the first end portion 30. The first end portion 30 includes a widened end portion 38 on which electrical components may be mounted.

In the embodiment shown, the second end portion 32 is folded to be perpendicular to the adjacent end of the second end portion 32 and received through a side wall of the case 20 to be located between the transducers 14a and 14b and the first end 22 of the body 12. The first end portion 30 includes a further bend to define an intermediate section 40 of the first end portion 30 located adjacent the body 12. The intermediate section 40 is therefore parallel to the longitudinal axis of the body 12 and perpendicular to the second end portion 32. The remainder of the first end portion 30 of the connection member 18 extends away from the body 12 and is perpendicular to the central longitudinal axis of the body 12.

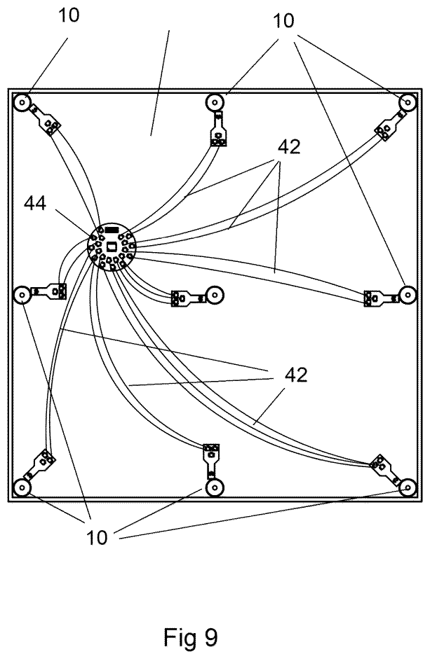

A plurality of the wear sensors 10 are installed on the back of a wear plate 11 to form part of a wear monitoring system, as can be seen in FIG. 9. Ultrasonic signals are emitted from the first ultrasonic transducers 15a towards a front surface of the wear plate and reflected ultrasonic signals are received by the second ultrasonic transducer 15b. Cables 42 extend from a junction unit 44 to each of the wear sensors 10 provided on the wear plate 11. The cables 42 send signals to the first ultrasonic transducers 14 and receive back signals from the second ultrasonic transducers 14b. The received signals can be used by the wear monitoring system to determine the thickness of the wear plate 11 and thereby monitor wear.

While the embodiment shown in the drawings uses cables 42 to connect from the wear sensors, other embodiments may use alternative connections. For example, the connections may be traces provided by direct printing or screening on the liner or by a flexible membrane electronics trace board.

The junction unit 44 is connected to a transceiver unit (not shown). The transceiver unit may be located within a housing 46 mounted to one of the securing bolts provided to mount the wear plate 11. The junction unit 44 may include circuitry in order to add identification data to the information received from each of the wear sensors 10. The identification data is used to identify the wear plate 11 on which the wear sensors 10 are installed. The transceiver unit is provided to wirelessly transmit wear data to a remote device for storage and analysis.

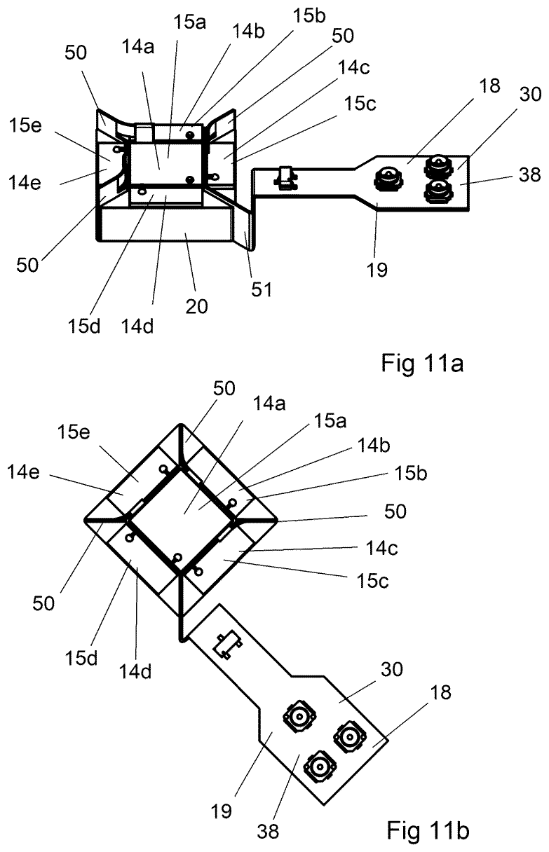

FIGS. 11 to 13 show a second embodiment of a wear sensor 10 in accordance with the present invention. The wear sensor 10 of FIGS. 11 to 13 is similar to the previous embodiment and like numerals are used to denote like parts.

The wear sensor 10 of FIGS. 11 to 13 is provided with a larger number of ultrasonic transducers 14. In this embodiment, five such ultrasonic transducers 14a, 14b, 14c, 14d and 14e are provided. Each of the ultrasonic transducers 14 comprises a corresponding piezo element 15a to 15e. The body 12 of the wear sensor 10 is rectangular rather than circular and the first to fifth piezo elements 15a to 15e are also each rectangular and arranged coplanar.

The first piezo element 15a is arranged centrally and the second, third, fourth and fifth piezo elements 15b, 15c, 15d and 15e are each arranged adjacent one of the sides of the first piezo element 15a. In the embodiment shown, the first piezo element 15a receives signals transmitted from the second to fifth piezo elements 15b to 15e. It is expected that this arrangement using additional piezo elements 15 will provide better detection of wearing of the surface, regardless of the directionality of the wear pattern of the surface.

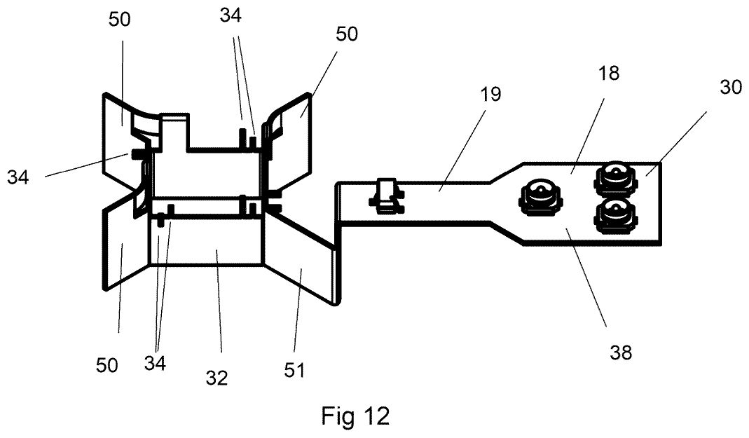

The second end portion 32 of the connection member 18 is provided with a pair of tabs to connect to each of the piezo elements 15. The second end portion 32 is to be folded in use as can be seen in FIG. 12 such that the first side edge 36 extends between adjacent edges of the piezo elements 15 so that the tabs 34 may be folded to connect with the piezo elements 15. In the embodiment shown, the second end portion 32 is folded into a rectangular shape to pass around the edge of the first piezo element 15.

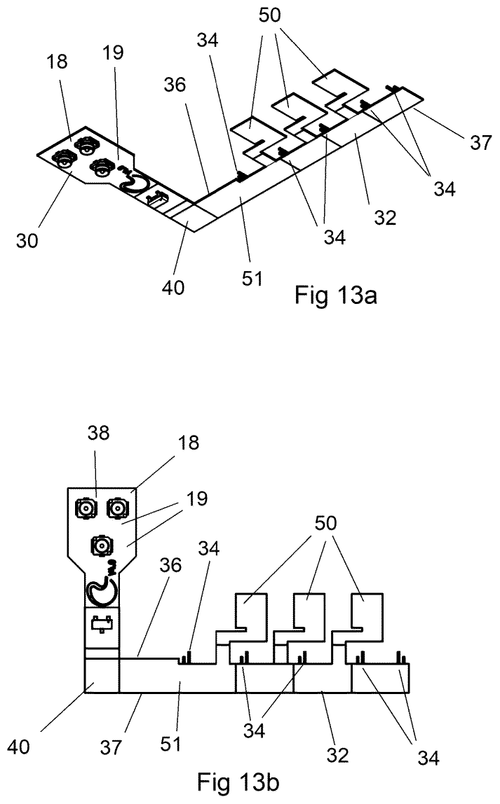

The connection member 18 includes also a plurality of insulation tabs 50. Each of the insulation tabs 50 is formed as part of the planar structure of the connection member 18, as can be seen in FIG. 13. The insulation tabs 50 are foldable such that, in the folded position (as seen in FIGS. 11 and 12), each of the insulation tabs 50 extends between an adjacent pair of the piezo elements 15. The insulation tabs 50 include conductive material and are grounded in use to provide insulation between the adjacent pairs of piezo elements 15.

In the embodiment shown, each of the insulation tabs 50 in the folded position extends diagonally outwardly from the corners of the rectangular structure formed by the folded second portion 32 of the connection member 18. Only three such insulation tabs 50 are provided extending outwardly from the first edge of the second portion 32 of the connection member 18 and the end of the second end portion 32 of the connection member 18 adjacent the intermediate section 40 acts as a further insulation portion 51 between an adjacent pair of piezo elements 15.

It will be readily apparent to persons skilled in the relevant arts that various modifications and improvements may be made to the foregoing embodiments, in addition to those already described, without departing from the basic inventive concepts of the present invention.

What is claimed is:

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. A wear sensor comprising:
a body including at least first and second ultrasonic transducers for sending and/or receiving ultrasonic signals; and
a connection member comprising a planar first end portion having connectors thereon for receiving signals from and sending signals to the ultrasonic transducers, and a planar second end portion having a plurality of tabs extending outwardly from a first side edge thereof connected by conductors on the connection member to the connectors;
wherein the second end portion is embedded within the body of the wear sensor adjacent the first and second ultrasonic transducers and wherein the tabs are bent out of the plane of the second end portion of the connection member for connection to the transducers.

20. The wear sensor in accordance with claim 19, wherein the first and second transducers comprise planar piezo elements and the second end portion of the connection member is oriented within the body perpendicular to the piezo elements with a first side edge thereof adjacent the piezo elements.

21. The wear sensor in accordance with claim 20, wherein the body is cylindrical and the first and second piezo elements are co-planar and semi-circular and wherein the second end portion of the connection member is oriented such that the first side edge is adjacent central edges of the piezo elements.

22. The wear sensor in accordance with claim 21, wherein four tabs are provided such that each of the piezo elements may have one of the tabs folded adjacent a first surface thereof and one of the tabs folded to be adjacent a second surface thereof.

23. The wear sensor in accordance with claim 22, wherein the first side edge includes recessed portions such that one of the tabs for connection to each of the piezo elements extends from the recessed portion.

24. The wear sensor in accordance with claim 19, wherein the connection member comprises a flexible board and the second end portion is folded to be perpendicular to the first end portion.

25. The wear sensor in accordance with claim 24, wherein the first end portion includes a further bend to define an intermediate section of the first end portion located adjacent the body such that intermediate section is parallel to the longitudinal axis of the body and perpendicular to the second end portion and such that the first end portion of the connection member extends away from the body being perpendicular to the central longitudinal axis of the body.

26. The wear sensor in accordance with claim 19, wherein the body includes a backing layer adjacent a second end of the body and a matching layer adjacent the first end.

27. The wear sensor in accordance with claim 26, wherein the matching layer has a depth greater than the backing layer such that the transducers are located closer to the second end of the body than the first end.

28. The wear sensor in accordance with claim 26, wherein surfaces of the matching layer adjacent the transducers are angled such that the first and second piezo elements are angled relative to each other.

29. The wear sensor in accordance with claim 19, wherein a case is provided to receive the body.

30. The wear sensor in accordance with claim 29, wherein the body includes also a cap extending across the case at the second end thereof above the backing layer.

31. The wear sensor in accordance with claim 19, wherein the body is rectangular.

32. The wear sensor in accordance with claim 31, wherein there are provided third, fourth and fifth piezo elements with each of the piezo element being rectangular.

33. The wear sensor in accordance with claim 32, wherein the second, third, fourth and fifth piezo elements are each located adjacent a side of the first piezo element.

34. The wear sensor in accordance with claim 31, wherein the second end portion of the connection member includes bends such that the first edge thereof extends between adjacent pairs of piezo elements.

35. The wear sensor in accordance with claim 32, wherein insulation tabs are provided extending outwardly from the second end portion of the connection member, the insulation tabs being foldable to extend between an adjacent pair of the piezo elements.

36. The wear sensor in accordance with claim 35, wherein the insulation tabs include conductive material and are ground to provide the insulation.
